(19) United States
(12) Patent Application Publication
(10) Pub. No.: US 2026/0085398 A1
(43) Pub. Date: Mar. 26, 2026

(54) SEMICONDUCTOR PROCESSING TOOL AND METHODS OF OPERATION

(71) Applicant: Taiwan Semiconductor Manufacturing Company, Ltd., Hsinchu (TW)

(72) Inventors: Cheng-Yun LEE, Taoyuan City (TW); Kuan-Chia CHEN, Hsinchu City (TW); Che-Wei TIEN, Kaohsiung (TW); Min-Jung YANG, Taitung (TW)

(73) Assignee: Taiwan Semiconductor Manufacturing Company, Ltd., Hsinchu (TW)

(21) Appl. No.: 18/893,336

(22) Filed: Sep. 23, 2024

(51) Int. Cl. C23C 14/34; C23C 14/50; H01J 37/32; H01J 37/34; H01L 21/285

(52) U.S. Cl. CPC C23C 14/345; C23C 14/505; H01J 37/32724; H01J 37/3467; H10P 14/44; H01J 2237/332

(57) ABSTRACT

A deposition tool includes a rotatable chuck and/or a pulsed direct current (DC) bias source. The pulsed DC source may be used to pulse a DC power in the processing chamber to achieve a lower electron temperature in the processing chamber, which enables the material from a material target to be directed toward the semiconductor substrate in a highly directional manner. This enables a low angle of deposition to be achieved for depositing the material, which enables the material to be evenly and symmetrically deposited onto sidewalls of recesses in the semiconductor substrate. Additionally and/or alternatively, the rotatable chuck may be used to rotate the semiconductor substrate during deposition of the layer onto the semiconductor substrate to compensate for nonuniformities in the deposition rate of the layer across the semiconductor substrate. This enables a high horizontal thickness uniformity across the semiconductor substrate.

### BACKGROUND

A physical vapor deposition (PVD) tool, such as a sputtering tool (or sputter deposition tool) includes a semiconductor processing tool that performs a physical vapor deposition operation within a processing chamber to deposit material onto a semiconductor substrate such as a wafer. The material may include a metal, a dielectric, or another type of material. A physical vapor deposition operation (such as a sputtering operation) may include placing the semiconductor substrate on an anode in a processing chamber, in which a gas is supplied and ignited to form a plasma of ions of the gas. The ions in the plasma are accelerated toward a cathode formed of the material to be deposited, which causes the ions to bombard the cathode and release particles of the material. The anode attracts the particles, which causes the particles to travel toward and deposit onto the semiconductor substrate.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example semiconductor processing tool described herein.

FIG. 2 is a diagram of an example deposition tool described herein for use in the semiconductor processing tool of FIG. 1.

FIG. 3 is a diagram of an example of operating the deposition tool described herein.

FIGS. 4A-4D are diagrams of an example implementation of a cyclic deposition process described herein.

FIG. 5 is a diagram of an example implementation of a pulsing technique for a direct current (DC) bias source of the example deposition tool described herein.

FIG. 6 is a diagram of example components of a device described herein.

FIG. 7 is a flowchart of an example process associated with performing a deposition operation using a deposition tool described herein.

FIG. 8 is a flowchart of an example process associated with performing a deposition operation using a deposition tool described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A processing chamber of a physical vapor deposition (PVD) tool may include a material target and a chuck (e.g., an electrostatic chuck or a vacuum chuck) on which a semiconductor substrate is positioned below the target structure. During a PVD operation, such as a sputtering operation, material sourced from the material target is deposited onto the semiconductor substrate using a plasma formed from a gas supplied between the material target and the semiconductor substrate. Ions in the plasma may be accelerated toward the material target, which removes material that then travels toward the semiconductor substrate in the processing chamber.

A PVD tool may be used to deposit layers and/or structures of semiconductor devices. In some cases, a high thickness uniformity for the layer that is deposited using the PVD tool may be difficult to achieve. For example, the thickness of the layer may vary across the semiconductor substrate due to inconsistent deposition rates across the across the semiconductor substrate. The inconsistent deposition rates may occur, at least in part, due to a low directionality of travel for the material of the layer that is deposited. The low directionality leads to a wide angle of deposition, which can result in a faster rate of accumulation of material on outer sidewalls of recesses near the edge of the semiconductor substrate than inner sidewalls of the recesses. This can lead to defect formation in the layer, such as voids and other discontinuities, which can degrade the performance of semiconductor devices formed on the semiconductor substrate and/or can lead to reduced yield of semiconductor devices.

In some implementations described herein, a deposition tool (e.g., a PVD tool or sputtering tool) includes a rotatable chuck and/or a pulsed direct current (DC) bias source. The rotatable chuck and/or the pulsed DC source enable the deposition tool to be used to deposit a layer onto a semiconductor substrate with high horizontal thickness uniformity across the semiconductor substrate and/or with high vertical thickness symmetry (e.g., particularly near the perimeter of the semiconductor substrate).

The pulsed DC source may be used to pulse a DC power in the processing chamber to achieve a lower electron temperature in the processing chamber, which enables the material from a material target to be directed toward the semiconductor substrate in a highly directional manner. This enables a low angle of deposition to be achieved for depositing the material, which enables the material to be evenly and symmetrically deposited onto sidewalls of recesses in the semiconductor substrate.

Additionally and/or alternatively, the rotatable chuck may be used to rotate the semiconductor substrate during deposition of the layer onto the semiconductor substrate to compensate for nonuniformities in the deposition rate of the layer across the semiconductor substrate. This enables a high horizontal thickness uniformity across the semiconductor substrate.

The pulsed DC source and the rotatable chuck may be used to perform a cyclic deposition process to deposit the layer. Each cycle may include using the pulsed DC source to deposit a portion of the layer, and rotating the semiconductor substrate using the rotatable chuck. The cyclic deposition process may include a plurality of such cycles to achieve a high thickness uniformity (both horizontal and vertical thickness uniformity) in the layer.

In this way, the pulsed DC source and/or the rotatable chuck may reduce the rate of defect formation in semiconductor devices formed on the semiconductor substrate, which may increase the yield of the semiconductor devices and/or may increase the performance of the semiconductor devices.

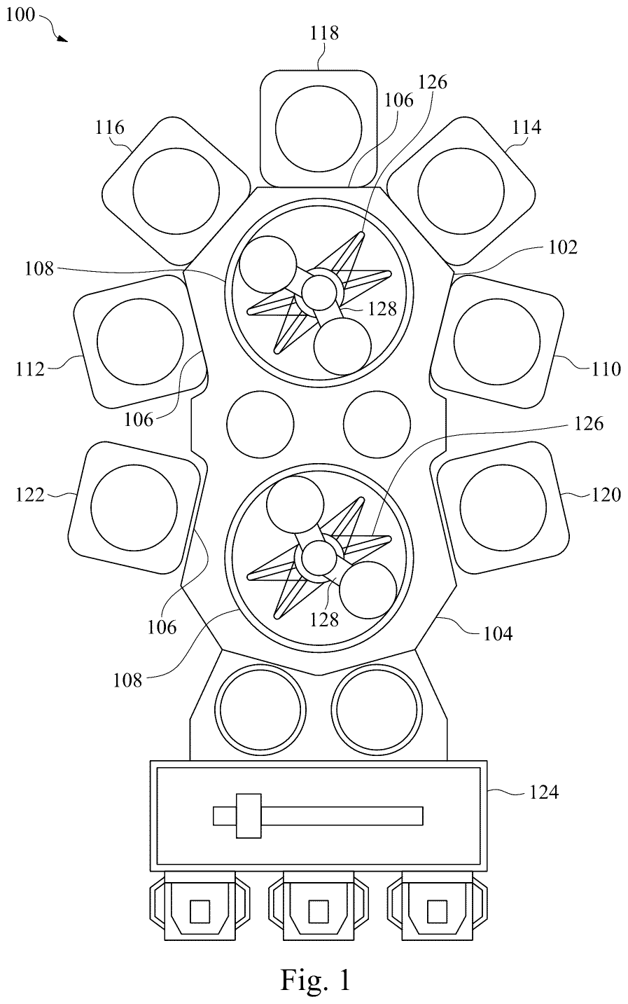

FIG. 1 is a diagram of an example semiconductor processing system 100 described herein. The semiconductor processing system 100 may perform one or more deposition processes, such as a physical vapor deposition (PVD) process, a chemical vapor deposition (CVD) process, a plasma-enhanced CVD (PECVD) process, a high-density plasma CVD (HDP-CVD) process, a sub-atmospheric CVD (SACVD) process, an atomic layer deposition (ALD) process, and/or a plasma-enhanced atomic layer deposition (PEALD) process, among other examples. As described herein, a physical vapor deposition process may correspond to a sputtering process.

In some implementations, and as shown in FIG. 1, the semiconductor processing system 100 includes one or more main frame structures 102, 104 having a plurality of sidewalls 106. The main frame structures 102, 104 and the plurality of sidewalls 106 may provide structural support to the semiconductor processing system 100.

A plurality of vacuum load lock chambers 108 is located in the center of main frame structures 102, 104. In some implementations, one or more of the vacuum load lock chambers 108 is maintained in a vacuum state to stage semiconductor substrates (e.g., silicon wafers, among other examples) for processing within the semiconductor processing system 100 to receive the semiconductor substrates after processing within the semiconductor processing system 100. Each of the plurality of vacuum load lock chambers 108 spatially separates the semiconductor substrates from processing chambers of the semiconductor processing system 100.

The semiconductor processing system 100 includes a plurality of processing chambers 110, 112, 114, 116, 118, 120, and 122. Each processing chamber may include one or more components to deposit material using a deposition process onto a semiconductor substrate received from one of the plurality of vacuum load lock chambers 108.

An external semiconductor substrate elevator 124 is located adjacent to the semiconductor processing system 100. In some implementations, the external semiconductor substrate elevator 124 is a part of the semiconductor processing system 100. In some implementations, the external semiconductor substrate elevator 124 is a component that is separate from the semiconductor processing system 100. The external semiconductor substrate elevator 124 is configured to hold a cassette containing a plurality of semiconductor substrates. The external semiconductor substrate elevator 124 also includes an automatic distributor for selecting a semiconductor substrate from the plurality of semiconductor substrates and timely supplying the selected semiconductor substrate to one of the plurality of vacuum load lock chambers 108 to stage for processing by one of the processing chambers 110-122.

The semiconductor processing system 100 may further include, within one or more of the plurality of vacuum load lock chambers 108, a semiconductor substrate transfer system 126 including a plurality of robotic arms 128. The semiconductor substrate transfer system 126, including the plurality of robotic arms 128, may operate in conjunction with the external semiconductor substrate elevator 124 to transport semiconductor substrates amongst a cassette on the external semiconductor substrate elevator 124, and to and/or from one or more of the processing chambers 110-122.

One or more of the processing chambers 110-122 may be subjected to a deposition operation to clean the one or more of the processing chambers 110-122 and to maintain a degree of cleanliness in the one or more of the processing chambers 110-122. Examples of such a deposition operation include a burn-in deposition operation that forms a plasma to remove particulates from a target structure material within the one or more of the processing chambers 110-122, a pasting deposition operation that coats an interior surface within the one or more of the processing chambers 110-122 to prevent flaking of particulates from the interior surface, and/or another deposition operation.

As indicated above, FIG. 1 is provided as an example. Other examples may differ from what is described with regard to FIG. 1. For example, another example may include additional components, fewer components, different components, or differently arranged components than those shown in FIG. 1. Additionally, or alternatively, a set of components (e.g., one or more components) of FIG. 1 may perform one or more functions described herein as being performed by another set of components.

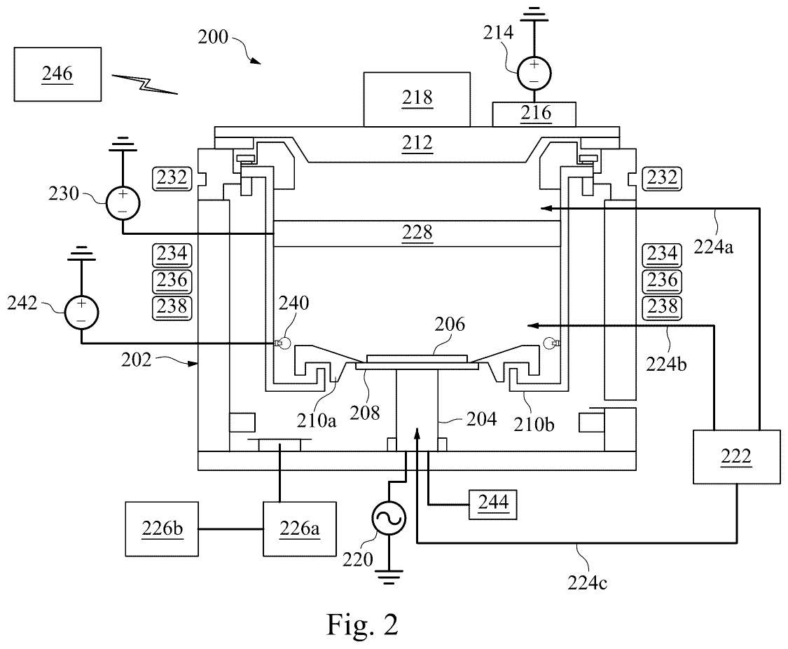

FIG. 2 is a diagram of an example deposition tool 200 described herein. In some implementations, the deposition tool 200 may be included in the semiconductor processing system 100 of FIG. 1. The deposition tool 200 includes a processing chamber 202 which may correspond to one of the processing chambers 110-122 as described in connection with FIG. 1. The deposition tool 200 may include or may be a PVD deposition tool (or sputter deposition tool) that is configured to deposit material onto semiconductor substrates (and/or other types of substrates such as silicon-on-insulator (SOI) substrates) by PVD.

The deposition tool 200 further includes a pedestal 204 in the processing chamber 202. A semiconductor substrate 206 may be supported on a rotatable chuck 208 (e.g., an electrostatic chuck (ESC) or a vacuum chuck, among other examples) that is included on the pedestal 204. The pedestal 204 and the associated rotatable chuck 208 may be, for example, fabricated from aluminum, stainless steel, ceramic, or combinations thereof.

The rotatable chuck 208 may be configured to be rotated such that the semiconductor substrate 206 is rotated by the rotatable chuck 208. In some implementations, the pedestal 204 also rotates, which rotates the rotatable chuck 208 (and thus, the semiconductor substrate 206 positioned thereon). In some implementations, the pedestal 204 includes a spindle to which the rotatable chuck 208 is attached, and the rotatable chuck 208 is configured to be rotated by the spindle.

The rotatable chuck 208 may be configured to be rotated to compensate for nonuniformities in the deposition rate in different regions or zones within the processing chamber 202 of the deposition tool 200. For example, some regions or zones in the processing chamber 202 (sometimes referred to as “hot spots”) may have higher deposition rates than other regions or zones (sometimes referred to as “cold spots”) in the processing chamber 202. Deposition tools (e.g., PVD tools) may have unique characteristics that vary from deposition tool to deposition tool, and one of those characteristics may include the deposition rate uniformity in different regions or zones within the processing chambers of the deposition tools. Moreover, the deposition rate uniformity within a processing chamber of a particular deposition tool can vary from deposition operation to deposition operation, and/or can vary for different types of materials that are deposited, among other examples. Thus, compensating for variation in deposition rate uniformity for a deposition tool by selection of deposition parameters can be difficult and not fully effective.

Rotating the semiconductor substrate 206 using the rotatable chuck 208 during a deposition process so that the semiconductor substrate 206 passes through the hot spots and cold spots in the processing chamber 202 enables the variation in deposition rate uniformity within the processing chamber 202 to be more evenly distributed across the entire semiconductor substrate 206. In this way, rotating the semiconductor substrate 206 using the rotatable chuck 208 during a deposition process enables a greater horizontal thickness uniformity to be achieved in a layer of material deposited onto the semiconductor substrate 206 than without the use of the rotatable chuck 208.

In some implementations, the rotatable chuck 208 is configured to partially rotate the semiconductor substrate 206 (e.g., to rotate the semiconductor substrate 206 less than a full 360-degree revolution) multiple times during a deposition process. For example, the rotatable chuck 208 is configured to rotate the semiconductor substrate 206 approximately 90 degrees and then keep the semiconductor substrate 206 in place for a period of time to allow material to be deposited onto the semiconductor substrate 206. Then the rotatable chuck 208 may be configured to partially rotate the semiconductor substrate 206 another approximately 90 degrees and then keep the semiconductor substrate 206 in place for another period of time to allow additional material to be deposited onto the semiconductor substrate 206. The rotatable chuck 208 may be configured to perform additional rotations in a similar manner during the deposition operation.

In some implementations, the rotatable chuck 208 may be configured to rotate the semiconductor substrate 206 greater than 0 degrees and up to approximately 180 degrees during a partial rotation. If the angle of rotation is too low or too high (e.g., is 0 degrees or greater than approximately 180 degrees), the variation in deposition rate uniformity within the processing chamber 202 may not be evenly distributed across the semiconductor substrate 206. However, other values and ranges for the partial rotation of the semiconductor substrate 206 are within the scope of the present disclosure.

The deposition tool 200 may include an upper shield 210a and a lower shield 210b. The upper shield 210a and the lower shield 210b may be positioned adjacent to (and laterally around) the rotatable chuck 208. The upper shield 210a may be supported by the lower shield 210b. The upper shield 210a and the lower shield 210b form a channel through which excess material and gasses in the processing chamber 202 may flow around the semiconductor substrate 206 and toward the bottom of the processing chamber 202. The upper shield 210a and the lower shield 210b may be fabricated from a material that can resist erosion plasma generated in the processing chamber 202, such as a stainless-steel material, a titanium material, an aluminum material, or a ceramic material, among other examples.

A material target 212 may be included in the processing chamber 202. The material target 212 may be located at the top of the processing chamber 202 such that the material target 212 is located above the rotatable chuck 208. This enables material removed from the material target 212 to fall downward (e.g., by gravitational force) onto the semiconductor substrate 206. The material target 212 may include a piece of material (e.g., a block, a layer) that is to be deposited on to the semiconductor substrate 206. In some implementations, the material target 212 includes a metal material such as copper (Cu), cobalt (Co), and/or ruthenium (Ru), among other examples. In some implementations, the material target 212 includes another material such as a tantalum nitride (TaN) material, among other examples.

The deposition tool 200 further includes a pulsed DC bias source 214 that is electrically coupled to an electrode on the processing chamber 202. The pulsed DC bias source 214 is configured to apply a pulsed DC bias (e.g., a pulsed DC voltage) to the material target 212. The pulsed DC bias causes free electrons in the processing chamber 202 to accelerate, which increases the energy of the electrons. When high-energy free electrons in the processing chamber 202 collide with a gas (e.g., an argon (Ar) gas and/or another gas), the high-energy free electrons cause the gas to ionize, which results in formation of a plasma within the processing chamber 202. An upper magnet 218 above the material target 212 may be used to confine the motion of the free electrons and to increase the density of the plasma within the processing chamber 202.

The electrons in the plasma may bombard the material target 212, which causes the electrons to remove material ions from the material target 212. For example, in implementations in which the material target 212 is copper, the ions may bombard the material target 212 and remove copper (Cu⁺) ions from the material target 212. A radio frequency (RF) bias source 220 of the deposition tool 200 may be used to apply an RF bias to the pedestal 204 and/or to the rotatable chuck 208 to attract the material ions to the semiconductor substrate 206. In some implementations, the frequency of the RF bias may be included in a range of approximately 10 megahertz to approximately 20 megahertz. However, other values and ranges are within the scope of the present disclosure.

The pulsed DC bias source 214 may be “pulsed” in that the DC bias is applied by the pulsed DC bias source 214 according to a duty cycle. In other words, the DC bias is applied in a plurality of on cycles (e.g., at a voltage in a range of approximately −3000 volts to approximately −1000 volts), where off time durations (during which a 0-volt DC bias is applied) are provided between sequential on cycles. The DC bias is pulsed by the pulsed DC bias source 214 to maintain a low electron temperature (Te) for the electrons in the plasma. The low electron temperature enables a low angular spread to be achieved for the flow of material ions toward the semiconductor substrate 206. The angular spread of the material ions may be determined according to:

$$θ = \sqrt{\frac{Ti ∝ Te}{V}}$$

where θ corresponds to the angular spread of the material ions, Ti corresponds to the temperature of ions in the plasma, Te corresponds to the temperature of the electrons in the plasma, and V corresponds to the voltage of the DC bias applied by the pulsed DC bias source 214. Thus, the lower the temperature of the electrons in the plasma, the lower the angular spread of the material ions that can be achieved. Accordingly, pulsing the DC bias that is applied by the pulsed DC bias source 214 to achieve a lower temperature for the electrons in the plasma enables a lower angular spread of the material ions to be achieved.

The low angular spread of the material ions results in a highly vertical angle of deposition of the material ions onto the semiconductor substrate 206. For example, the angle of deposition of the material ions onto the semiconductor substrate 206 may be in a range of approximately 85 degrees to approximately 95 degrees. Thus, the material ions deposit onto sidewalls in recesses in the semiconductor substrate 206 in a highly uniform manner (enabling a high vertical thickness uniformity to be achieved for a layer deposited on the sidewalls of the recesses) because of the highly vertical angle of deposition of the material ions. A lower or higher angle of deposition might otherwise result in a greater amount of material ions to be deposited onto some sidewalls of the recesses at a greater rate than on other sidewalls, resulting in non-uniform sidewall thicknesses in a layer that is deposited in the recesses. However, other values and ranges for the angle of deposition of the material ions onto the semiconductor substrate 206 are within the scope of the present disclosure.

The deposition tool 200 includes a gas supply system that includes one or more mass flow controllers 222 that supply one or more gas flows into the processing chamber 202. For example, one or more mass flow controllers 222 may be used to provide gas flows 224a and 224b into the processing chamber 202 for generating a plasma. The one or more mass flow controllers 222 may control a rate of flow of the gas flows 224a and/or 224b (which may include argon (Ar), krypton (Kr), and/or another gas), which controls one or more parameters of the plasma including the ionization rate in the plasma, the ion passivation rate on the semiconductor substrate 206, and/or another parameter. In some implementations, a ratio of the flow rate of the gate-gas flow 224a to the flow rate of the gas flow 224b may be included in a range of approximately 5:1 to approximately 15:1. However, other values and ranges are within the scope of the present disclosure. As another example, one or more mass flow controllers 222 may be used to provide a gas flow 224c to the chuck for checking if a semiconductor substrate 206 is positioned on the rotatable chuck 208. In some implementations, a ratio of the flow rate of the gate-gas flow 224a to the flow rate of the gas flow 224c may be included in a range of approximately 5:1 to approximately 15:1. However, other values and ranges are within the scope of the present disclosure.

The deposition tool 200 further includes one or more vacuum pumps, including a cryo pump 226a and/or a system pump 226b, among other examples. The vacuum pumps may be connected to the processing chamber 202 and configured to create a vacuum in the processing chamber 202 during a deposition process and/or a deposition operation. For example, the cryo pump 226a may be used to create a vacuum pressure in the processing chamber of approximately 1×10⁻⁸ Torr or less. However, other values for the pressure in the processing chamber 202 are within the scope of the present disclosure. The vacuum may also be used to remove contaminants, excess material, and/or residual gasses from the processing chamber 202, among other examples.

The deposition tool 200 may further include a collimator 228 in the processing chamber 202. The collimator 228 may be configured to filter material neutrons removed from the material target 212 to achieve a higher ratio of material ions to material neutrons in the processing chamber 202. The higher ratio of material ions to material neutrons in the processing chamber 202 enables the RF bias applied to the rotatable chuck 208 by the RF bias source 220 to more effectively control the flow of the material ions toward the semiconductor substrate 206. In some implementations, a positive DC bias (e.g., a positive DC voltage) may be applied to the collimator 228 using a collimator bias source 230. The positive DC bias reduces the loss of material ions (e.g., Cu⁺ ions) on the collimator 228.

In some implementations, additional magnets 232, 234, 236, and/or 238 are included around the processing chamber 202 to further control the plasma in the processing chamber 202 and/or to further control the flow of material ions in the processing chamber 202.

The deposition tool 200 further includes reflow heater elements 240 that are connected to a reflow DC source 242. The reflow heater elements 240 may be used to increase the temperature of the semiconductor substrate 206 to perform a reflow operation to reflow the material of a layer deposited onto the semiconductor substrate 206 using the deposition tool 200. In some implementations, the reflow heater elements 240 include resistive heating elements such as heating lamps. The reflow DC source 242 applies a reflow DC bias to the reflow heater elements 240, and the reflow heater elements 240 dissipate the reflow DC bias in the form of heat. In some implementations, the temperature of the reflow operation may range from approximately 300 degrees Celsius to approximately 450 degrees Celsius. However, other values and ranges for the temperature of the reflow operation are within the scope of the present disclosure.

The deposition tool 200 further includes a chuck actuator 244 that is configured to rotate the rotatable chuck 208. In some implementations, the chuck actuator 244 includes an electric motor (e.g., a DC motor, a magnetic motor) and/or another type of chuck actuator 244 that is capable of causing the rotatable chuck 208 to rotate.

The deposition tool 200 further includes a controller 246. The controller 246 (e.g., a processor, a combination of a processor and memory, among other examples) may be communicatively coupled to one or more components of the deposition tool 200, such as the pulsed DC bias source 214, the RF bias source 220, the mass flow controller(s) 222, the vacuum pumps 226a and/or 226b, the collimator bias source 230, the reflow DC source 242, and/or the chuck actuator 244, among other examples. The controller 246 communicate with these components on one or more wireless communication links, one or more wired communication links, and/or a combination of wireless and wired communication links.

The controller 246 may be configured to control the operation of one or more components of the deposition tool 200. For example, the controller 246 may be configured to provide signals to the pulsed DC bias source 214 to cause the pulsed DC bias source 214 to apply a pulsed DC bias to the material target 212. As another example, the controller 246 may be configured to provide signals to the RF bias source 220 to cause the RF bias source 220 to apply an RF bias to the rotatable chuck 208. As another example, the controller 246 may be configured to provide signals to the mass flow controller(s) 222 to cause the mass flow controller(s) 222 to provide the gas flows 224a, 224b, and/or 224c. As another example, the controller 246 may be configured to provide signals to the vacuum pumps 226a and/or 226b to generate a vacuum pressure within the processing chamber 202. As another example, the controller 246 may be configured to provide signals to the collimator bias source 230 to cause the collimator bias source 230 to apply a DC bias to the collimator 228. As another example, the controller 246 may be configured to provide signals to the reflow DC source 242 to cause the reflow DC source 242 to apply a reflow DC bias to the reflow heater elements 240. As another example, the controller 246 may be configured to provide signals to the chuck actuator 244 to cause the chuck actuator 244 to rotate the rotatable chuck 208.

The number and arrangement of devices shown in FIG. 2 are provided as one or more examples. In practice, there may be additional devices, fewer devices, different devices, or differently arranged devices than those shown in FIG. 2. Furthermore, two or more devices shown in FIG. 2 may be implemented within a single device, or a single device shown in FIG. 2 may be implemented as multiple, distributed devices.

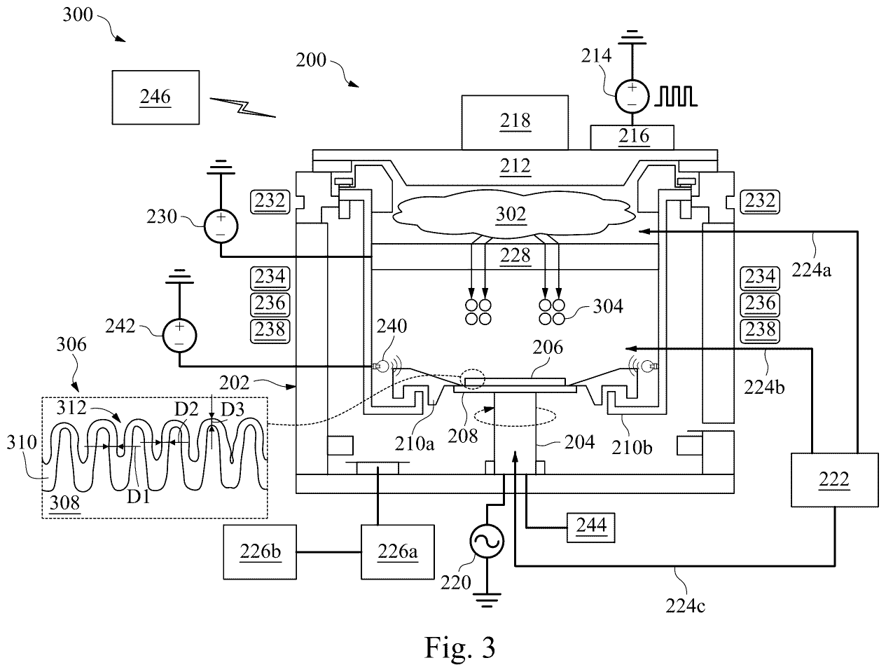

FIG. 3 is a diagram of an example 300 of operating the deposition tool 200 described herein. For example, the example 300 may include an example of operating the deposition tool 200 to perform a deposition procedure, which may include a PVD procedure or a sputter deposition procedure, among other examples.

As shown in FIG. 3, a plasma 302 may be generated in the processing chamber 202 of the deposition tool 200. The controller 246 may provide one or more signals (e.g., a voltage, an electrical current, a digital communication) to the pulsed DC bias source 214, which cause the pulsed DC bias source 214 to apply a pulsed DC bias to the material target 212 (e.g., through the electrode 216). The controller 246 may also provide one or more signals (e.g., a voltage, an electrical current, a digital communication) to the mass flow controller(s) 222, which causes the mass flow controller(s) 222 to provide the gas flows 224a and 224b into the processing chamber 202. The pulsed DC bias causes electrons within the processing chamber to collide with atoms (e.g., argon (Ar) atoms) in the gas flows 224a and 224b, which ionizes the atoms and generates the plasma 302.

Pulsing the DC bias that is applied to the material target 212 enables a lower temperature to be achieved for the electrons in the plasma 302 than if a non-pulsed DC bias were to be applied to the material target 212. The lower temperature for the electrons in the plasma 302 enable the electrons to remove the material ions 304 from the material target 212 in a more controlled manner, which enables a highly vertical path of travel for the material ions 304 toward the semiconductor substrate 206 to be achieved. In some implementations, pulsing the DC bias that is applied to the material target 212 enables a temperature included in a range of approximately 5 electron-volts (eV) to approximately 10 eV to be achieved for the electrons in the plasma 302. If the temperature of the electrons is greater than approximately 10 eV, the electrons may be too energetic, resulting in uncontrolled material removal from the material target 212 and a wider angular spread for the material ions 304 (which decreases the vertical/sidewall deposition thickness uniformity on the semiconductor substrate 206). Electron temperatures of less than approximately 5 eV may result in reduced ionization efficiency, resulting in increased concentration of material neutrons and lower deposition rates. However, other values and ranges other than approximately 5 eV to approximately 10 eV are within the scope of the present disclosure.

The upper magnet 218 may be used to control the bombardment of electrons in the plasma 302 onto the material target 212. The bombardment of electrons in the plasma 302 onto the material target 212 causes material ions 304 to be removed from the material target 212. The material ions 304 pass through the collimator 228, which captures material neutrons that may have also been removed from the material target 212. The controller 246 may provide one or more signals (e.g., a voltage, an electrical current, a digital communication) to the collimator bias source 230, which causes the collimator bias source 230 to apply a positive DC bias to the collimator 228 to reduce the amount of material ions 304 that are captured by the collimator 228.

The controller 246 may provide one or more signals (e.g., a voltage, an electrical current, a digital communication) to the RF bias source 220, which causes the RF bias source 220 to apply an RF bias to the rotatable chuck 208 to attract the material ions 304 toward the semiconductor substrate 206.

FIG. 3 illustrates a close-up view of an outer region 306 of a layer 308 of the semiconductor substrate 206 near a perimeter of the semiconductor substrate 206 in which a layer of material 310 (e.g., a metal layer, a copper layer, or another type of layer) is deposited in recesses 312 in the layer 308 of the semiconductor substrate 206. Difficulty in uniformly depositing the material ions on the sidewalls of the recesses 312 may be highest near the perimeter of the semiconductor substrate 206 because of wider ion deposition angles. However, the use of the pulsed DC bias source 214 to apply the pulsed DC bias to the material target 212 to remove the material ions 304 from the material target 212 using lower temperature electrons enables a more vertical deposition angle to be achieved near the perimeter of the semiconductor substrate 206 for the material ions 304. Thus, the use of the pulsed DC bias source 214 to apply the pulsed DC bias to the material target 212 to remove the material ions 304 from the material target 212 using lower temperature electrons enables a higher vertical thickness uniformity to be achieved for the layer of material 310 on the sidewalls of the recesses 312, particularly near the perimeter of the semiconductor substrate 206. For example, the thickness of the layer of material 310 on outer sidewalls (e.g., sidewalls closest to the edge of the semiconductor substrate 206) of the recesses 312 (indicated in FIG. 3 as a dimension D1) and the thickness of the layer of material 310 on inner sidewalls (e.g., sidewalls closest to the center of the semiconductor substrate 206) of the recesses 312 (indicated in FIG. 3 as a dimension D2) may be within approximately 0% to approximately 5% variation of each other. However, other values and ranges are within the scope of the present disclosure.

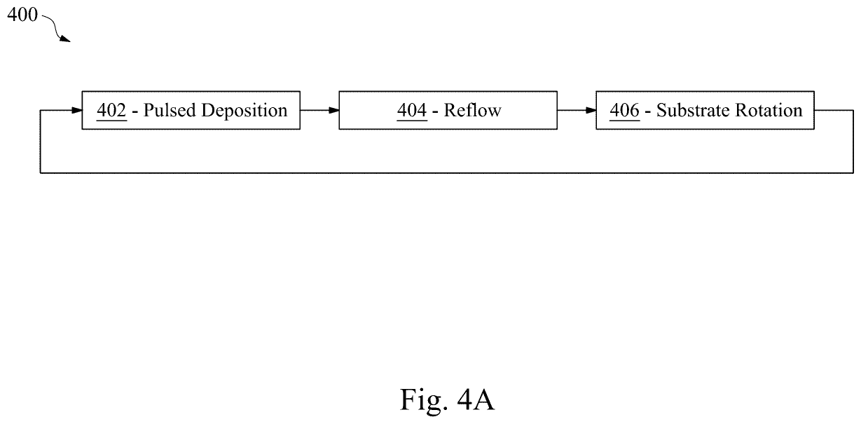

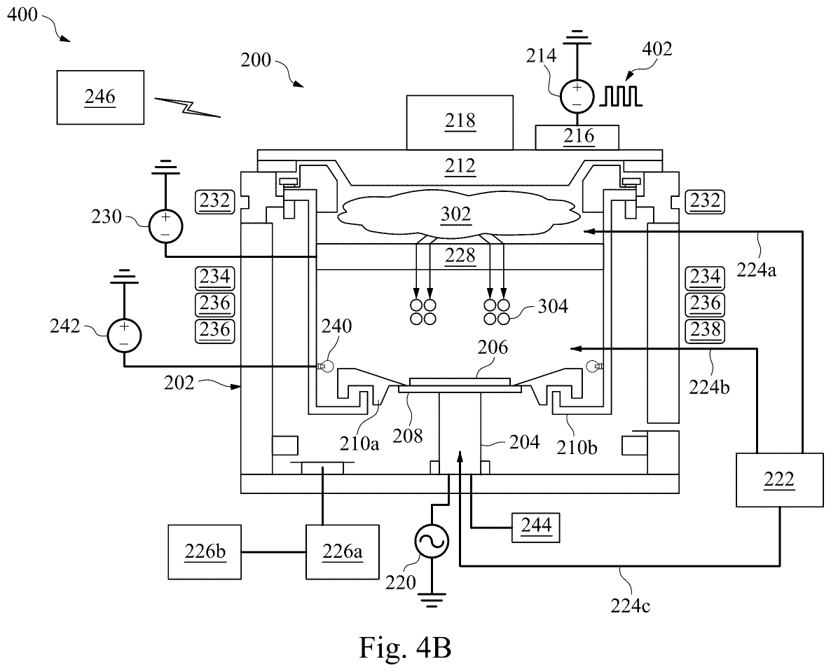

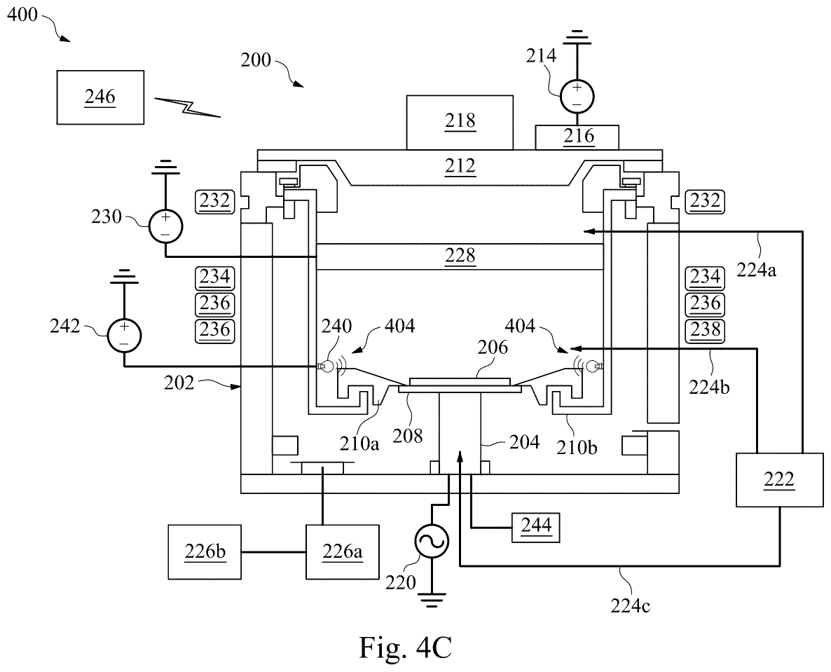

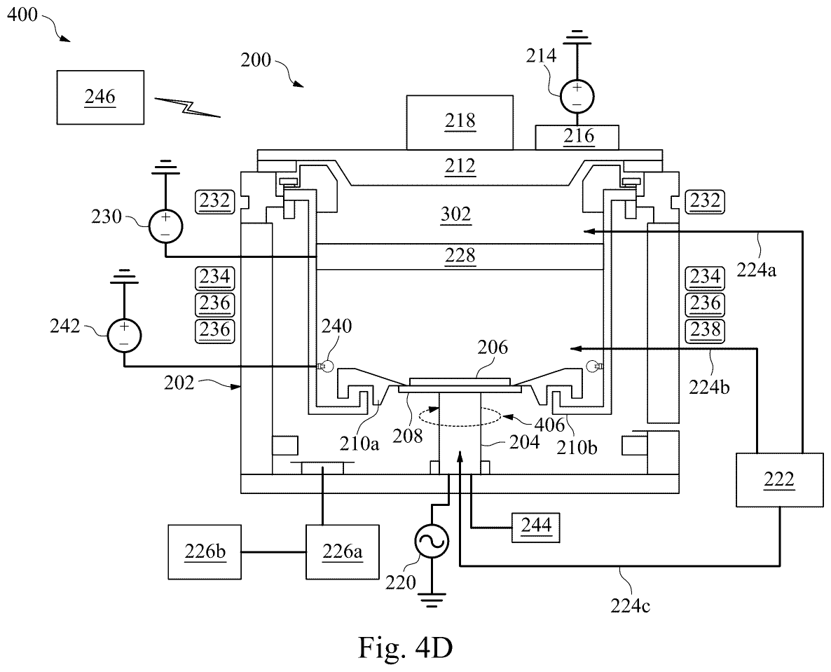

As further shown in FIG. 3, the controller 246 may provide one or more signals (e.g., a voltage, an electrical current, a digital communication) to the reflow DC source 242, which causes the reflow DC source 242 to apply a reflow DC bias to the reflow heater elements 240. This causes the reflow heater elements 240 to dissipate the reflow DC bias in the form of heat, which heats the semiconductor substrate 206. The reflow heater elements 240 may be used to heat the semiconductor substrate 206 to perform a reflow operation to reflow a layer of material 310 deposited onto the semiconductor substrate 206 using the deposition tool 200. In some implementations, the reflow operation may be performed after the material ions 304 are deposited onto the semiconductor substrate 206 to form the layer of material 310. In some implementations, the reflow operation may be performed as the material ions 304 are deposited onto the semiconductor substrate 206 to form the layer of material 310. In some implementations, a cyclic deposition process, such as the example cyclic deposition process illustrated and described in connection with FIGS. 4A-4D, may be performed in which the reflow operation is performed after the material ions 304 are deposited onto the semiconductor substrate 206 to form the layer of material 310 and prior to partially rotating the semiconductor substrate 206.

As further shown in FIG. 3, the controller 246 may provide one or more signals (e.g., a voltage, an electrical current, a digital communication) to the chuck actuator 244, which causes the chuck actuator 244 to rotate the rotatable chuck 208 (and thus, the semiconductor substrate 206). In some implementations, the semiconductor substrate 206 may be partially rotated (e.g., rotated less than 360 degrees) after the material ions 304 are deposited onto the semiconductor substrate 206 to form the layer of material 310. In some implementations, the semiconductor substrate 206 may be partially rotated (e.g., rotated less than 360 degrees) while the material ions 304 are deposited onto the semiconductor substrate 206 to form the layer of material 310. In some implementations, the semiconductor substrate 206 may be partially rotated (e.g., rotated less than 360 degrees) after a reflow operation is performed. In some implementations, a cyclic deposition process, such as the example cyclic deposition process illustrated and described in connection with FIGS. 4A-4D, may be performed in which the reflow operation is performed after the material ions 304 are deposited onto the semiconductor substrate 206 to form the layer of material 310 and prior to partially rotating the semiconductor substrate 206.

In some implementations, additional material ions 304 are deposited onto the semiconductor substrate 206 after the semiconductor substrate 206 is partially rotated. This enables the characteristics of the deposition rates across the processing chamber 202 to be distributed evenly across the semiconductor substrate 206. For example, if hot spots and cold spots occur in different regions of the processing chamber 202, rotating the semiconductor substrate 206 enables the areas of the semiconductor substrate 206 to be exposed to these regions of hot spots and cold spots so that these characteristics are evenly across the semiconductor substrate 206.

Thus, rotating the semiconductor substrate 206 enables a higher horizontal thickness uniformity to be achieved for the layer of material 310 across the semiconductor substrate 206. For example, the thickness of the layer of material 310 on the surface of the semiconductor substrate 206 (indicated in FIG. 3 as a dimension D3) may have approximately 0% to approximately 5% variation across the semiconductor substrate 206. However, other values and ranges are within the scope of the present disclosure.

As indicated above, FIG. 3 is provided as an example. Other examples may differ from what is described with regard to FIG. 3.

FIGS. 4A-4D are diagrams of an example implementation 400 of a cyclic deposition process described herein. The cyclic deposition process includes a deposition process in which the deposition tool 200 is used to perform a plurality of deposition-reflow-rotation cycles to deposit a layer of material 310 onto a semiconductor substrate 206 in a highly uniform manner.

FIG. 4A illustrates an overview of a deposition-reflow-rotation cycle of the cyclic deposition process. As shown in FIG. 4A, a pulsed deposition operation 402 may be performed to deposit material of a layer of material 310 onto the semiconductor substrate 206 using the pulsed DC bias source 214 to apply a pulsed DC bias to the material target 212 in the processing chamber. Next, a reflow operation 404 may be performed after the pulsed deposition operation 402. In the reflow operation 404, the layer of material 310 is heated to reflow the material of the layer so that the material redistributes in a more uniform manner. Next, a substrate rotation operation 406 may be performed in which the semiconductor substrate 206 is partially rotated. These operations may be repeated for a plurality of cycles to form the layer of material 310 to a desired thickness. In some implementations, a quantity of 2 cycles to 5 cycles is performed to form a layer of material 310 on the semiconductor substrate 206. However, other quantities of cycles for forming a layer of material 310 on a semiconductor substrate are within the scope of the present disclosure. Additionally and/or alternatively, the order of operations illustrated in FIG. 4A may be modified such that the pulsed deposition operation 402, the reflow operation 404, and/or the substrate rotation operation 406 are performed in a different order, and/or such that two or more of the pulsed deposition operation 402, the reflow operation 404, and/or the substrate rotation operation 406 are performed at least partially concurrently.

FIG. 4B illustrates an example pulsed deposition operation 402. As shown in FIG. 4B, the plasma 302 may be generated in the processing chamber 202 of the deposition tool 200. The controller 246 may provide one or more signals (e.g., a voltage, an electrical current, a digital communication) to the pulsed DC bias source 214, which cause the pulsed DC bias source 214 to apply a pulsed DC bias to the material target 212 (e.g., through the electrode 216). The controller 246 may also provide one or more signals (e.g., a voltage, an electrical current, a digital communication) to the mass flow controller(s) 222, which causes the mass flow controller(s) 222 to provide the gas flows 224a and 224b into the processing chamber 202. The pulsed DC bias causes electrons within the processing chamber to collide with atoms (e.g., argon (Ar) atoms) in the gas flows 224a and 224b, which ionizes the atoms and generates the plasma 302.

Pulsing the DC bias that is applied to the material target 212 enables a lower temperature to be achieved for the electrons in the plasma 302 than if a non-pulsed DC bias were to be applied to the material target 212. The lower temperature for the electrons in the plasma 302 enable the electrons to remove the material ions 304 from the material target 212 in a more controlled manner, which enables a highly vertical path of travel for the material ions 304 toward the semiconductor substrate 206 to be achieved.

In some implementations, the pulsed DC bias source 214 pulses the DC bias applied to the material target 212 at a frequency that is included in a range of approximately 5 kilohertz to approximately 50 kilohertz to achieve a temperature for the electrons in the plasma 302 that included in a range of approximately 5 eV to approximately 10 eV. If the pulse frequency is less than approximately 5 kilohertz, ignition of the plasma 302 may fail or a high concentration of material neutrons may result. If the pulse frequency is greater than 50 kilohertz, the deposition angle for the material ions 304 may be too wide, resulting in reduced symmetry in the thickness of the layer of material 310 that is formed on sidewalls of recesses 312 in the semiconductor substrate 206. However, other values and ranges other than approximately 5 kilohertz to approximately 50 kilohertz are within the scope of the present disclosure.

In some implementations, the controller 246 may provide one or more signals (e.g., a voltage, an electrical current, a digital communication) to the pulsed DC bias source 214, which cause the pulsed DC bias source 214 to adjust or modify the pulse frequency of the pulsed DC bias during the pulsed deposition operation 402. For example, the pulsed DC bias source 214 may increase or decrease the pulse frequency of the pulsed DC bias during the pulsed deposition operation 402 to tune the ion angle distribution of the material ions 304. In some implementations, the controller 246 determines the adjustments to the pulse frequency using a machine learning model. The machine learning model may include and/or may be associated with one or more of a neural network model, a random forest model, a clustering model, or a regression model. In some implementations, the controller 246 uses the machine learning model to determine the pulse frequency by providing candidate parameters (e.g., a pressure in the processing chamber 202, the deposition rates on the sidewalls of the recesses 312) as inputs to the machine learning model, and using the machine learning model to select a pulse frequency and a likelihood, probability, or confidence that a particular outcome (e.g., a thickness and/or profile of the layer of material 310) for a physical deposition operation will be achieved using the pulse frequency in view of the candidate parameters.

The controller 246 (or another system) may train, update, and/or refine the machine learning model to increase the accuracy of the outcomes and/or parameters determined using the machine learning model. The controller 246 may train, update, and/or refine the machine learning model based on feedback and/or results from the subsequent deposition operation, as well as from historical or related deposition operations (e.g., from hundreds, thousands, or more historical or related deposition operations) performed by the deposition tool 200.

The upper magnet 218 may be used to control the bombardment of electrons in the plasma 302 onto the material target 212. The bombardment of electrons in the plasma 302 onto the material target 212 causes material ions 304 to be removed from the material target 212. The material ions 304 pass through the collimator 228, which captures material neutrons that may have also been removed from the material target 212. The controller 246 may provide one or more signals (e.g., a voltage, an electrical current, a digital communication) to the collimator bias source 230, which causes the collimator bias source 230 to apply a positive DC bias to the collimator 228 to reduce the amount of material ions 304 that are captured by the collimator 228.

The controller 246 may provide one or more signals (e.g., a voltage, an electrical current, a digital communication) to the RF bias source 220, which causes the RF bias source 220 to apply an RF bias to the rotatable chuck 208 to attract the material ions 304 toward the semiconductor substrate 206.

FIG. 4C illustrates an example reflow operation 404. As shown in FIG. 4C, the controller 246 may provide one or more signals (e.g., a voltage, an electrical current, a digital communication) to the reflow DC source 242, which causes the reflow DC source 242 to apply a reflow DC bias to the reflow heater elements 240. This causes the reflow heater elements 240 to dissipate the reflow DC bias in the form of heat, which heats the layer of material 310 on the semiconductor substrate 206. The reflow heater elements 240 may be used to heat the layer of material 310 on the semiconductor substrate 206 to perform a reflow operation to reflow the layer of material 310 deposited onto the semiconductor substrate 206. In some implementations, the layer of material 310 is heated to a temperature that is included in a range of approximately 200 degrees Celsius to approximately 600 degrees Celsius in implementations in which the layer of material 310 is formed of copper. However, other materials and temperature ranges for the reflow operation 404 are within the scope of the present disclosure.

FIG. 4D illustrates an example substrate rotation operation 406. As shown in FIG. 4D, the controller 246 may provide one or more signals (e.g., a voltage, an electrical current, a digital communication) to the chuck actuator 244, which causes the chuck actuator 244 to rotate the rotatable chuck 208 (and thus, the semiconductor substrate 206). In some implementations, the semiconductor substrate 206 may be partially rotated (e.g., rotated less than 360 degrees) in the substrate rotation operation 406. In some implementations, the controller 246 determines a rotational profile for the substrate rotation operation 406 using a machine learning model. The machine learning model may include and/or may be associated with one or more of a neural network model, a random forest model, a clustering model, or a regression model. In some implementations, the controller 246 uses the machine learning model to determine the rotational profile (e.g., a rotation angle, or amount of rotation) for the substrate rotation operation 406 by providing candidate parameters (e.g., an angle of rotation, a direction of rotation, and/or pauses in rotation) as inputs to the machine learning model, and using the machine learning model to determine a likelihood, probability, or confidence that a particular outcome (e.g., a thickness and/or profile of the layer of material 310) will be achieved using the candidate parameters.

The controller 246 (or another system) may train, update, and/or refine the machine learning model to increase the accuracy of the outcomes and/or parameters determined using the machine learning model. The controller 246 may train, update, and/or refine the machine learning model based on feedback and/or results from the subsequent deposition operation, as well as from historical or related deposition operations (e.g., from hundreds, thousands, or more historical or related deposition operations) performed by the deposition tool 200.

As indicated above, additional cycles including the operations illustrated and described in connection with FIGS. 4B-4D may be performed to deposit additional material of the later of material 310 onto the semiconductor substrate 206. In some implementations, different parameters are used for different cycles. For example, different pulse frequencies for the pulsed DC bias applied by the pulsed DC bias source 214 to the material target 212 may be used in the pulsed deposition operations 402 of different cycles. As another example, different voltages for the pulsed DC bias applied by the pulsed DC bias source 214 to the material target 212 may be used in the pulsed deposition operations 402 of different cycles. As another example, different reflow temperatures may be used in the reflow operations 404 of different cycles. As another example, different rotation angles for partially rotating the semiconductor substrate 206 may be used in the substrate rotation operations 406 of different cycles.

As indicated above, FIGS. 4A-4D are provided as examples. Other examples may differ from what is described with regard to FIGS. 4A-4D. For example, another example may include additional operations, fewer operations, different operations, or differently arranged operations than those shown in FIGS. 4A-4D.

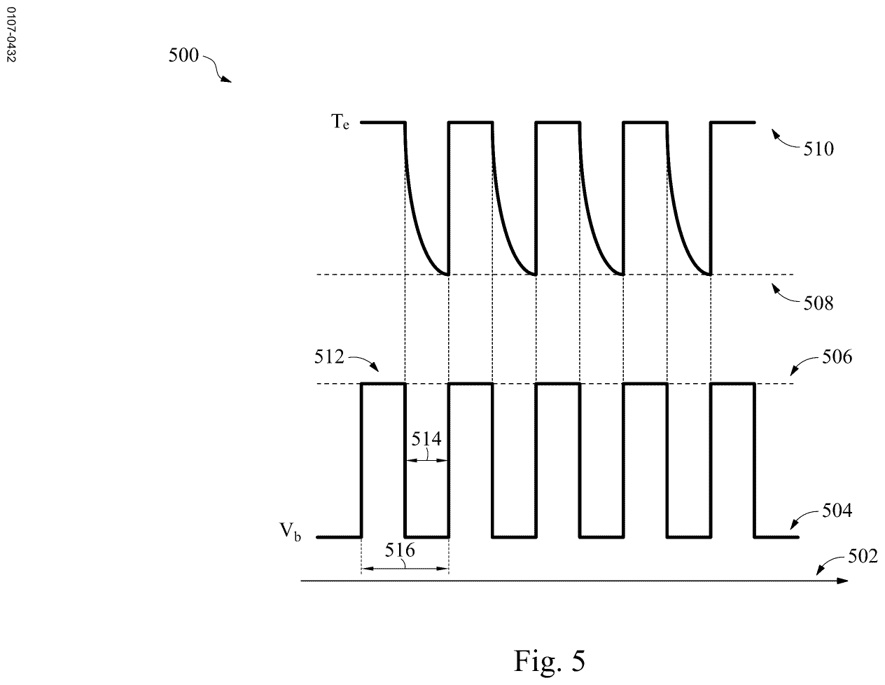

FIG. 5 is a diagram of an example implementation 500 of a pulsing technique for the pulsed DC bias source 214 of the deposition tool 200 described herein. The pulsing technique illustrated in FIG. 5 may be used in the pulsed deposition operation 402 illustrated and described in FIG. 4B to apply the pulsed DC bias to the material target 212.

As shown in FIG. 5, the pulsed DC bias may be pulsed as a function of time 502 in that voltage of the pulsed DC bias (V_{b}) may be modulated between a low voltage 504 (e.g., a 0 voltage) and a high voltage 506 (e.g., a negative voltage). Modulation of the voltage of the pulsed DC bias results in modulation of the temperature of electrons (Te) in the plasma 302 generated in the processing chamber 202 of the deposition tool 200 between a low temperature 508 (e.g., approximately 0 eV to approximately 1 eV) and a high temperature 510 (e.g., approximately 5 eV to approximately 10 eV). The low temperature 508 may be approximately 10% or less of high temperature 510. However, other values are within the scope of the present disclosure.

The voltage of the pulsed DC bias may be pulsed as a function of time 502 in a plurality of on pulses 512 in which the voltage of the pulsed DC bias is applied at the high voltage 506. An on pulse 512 may be followed by an off time duration 514 in which the voltage of the pulsed DC bias is applied at the low voltage 504. The ratio of the duration of an on pulse 512 to a subsequent off time duration 514 corresponds to the duty cycle 516 of the pulsed DC bias source 214. For example, an approximately 50% duty cycle 516 refers to a ratio of the duration of an on pulse 512 to a subsequent off time duration 514 of approximately 1:1. Thus, the pulsed DC bias applied by the pulsed DC bias source 214 may be pulsed based on the duty cycle 516 of the pulsed DC bias source 214. In some implementations, the duty cycle 516 may range from approximately 30% to approximately 70%. However, other values and ranges for the duty cycle are within the scope of the present disclosure.

The time duration of each duty cycle 516 may be based on the pulse frequency of the pulsed DC bias source 214. For example, the higher the pulse frequency the shorter the duration of the duty cycles 516. Conversely, the lower the pulse frequency the longer the duration of the duty cycles 516. In some implementations, the durations of the duty cycles 516 of the pulsed DC bias source 214 are different for different pulsed deposition operations 402. In some implementations, the ratio of the durations of on pulses 512 to the durations of off time durations 514 of the pulsed DC bias source 214 are different for different pulsed deposition operations 402. Thus, the pulsed DC bias source 214 may pulse the pulsed DC bias that is applied to the material target 212 based on different duty cycles 516 for different pulsed deposition operations 402.

As further shown in FIG. 5, the temperature of electrons in the plasma 302 rises to the high temperature 510 during the on pulses 512 and decreases to the low temperature 508 during the off time durations. An off time duration between two on pulses of the plurality of on pulses, corresponds to a relaxation time of the electrons in the plasma 302. In other words, for a 10 kilohertz pulsed DC bias having an approximately 50 microsecond off time duration 514, the temperature of the electrons in the plasma 302 drop to the low temperature 508 after a relaxation time of approximately 50 microseconds. However, other values for these parameters are within the scope of the present disclosure.

As indicated above, FIG. 5 is provided as an example. Other examples may differ from what is described with regard to FIG. 5.

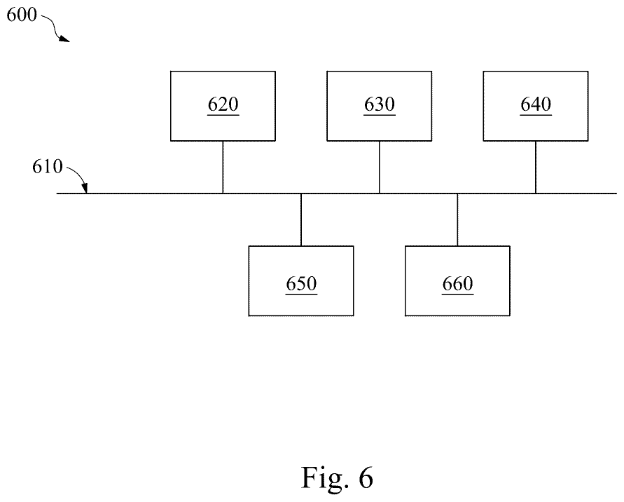

FIG. 6 is a diagram of example components of a device 600 described herein. The device 600 may correspond to the RF bias source 220, the pulsed DC bias source 214, the mass flow controller(s) 222, the cryo pump 226a, the system pump 226b, the collimator bias source 230, the reflow DC source 242, the chuck actuator 244, and/or the controller 246. In some implementations, the RF bias source 220, the pulsed DC bias source 214, the mass flow controller(s) 222, the cryo pump 226a, the system pump 226b, the collimator bias source 230, the reflow DC source 242, the chuck actuator 244, and/or the controller 246 may include one or more devices 600 and/or one or more components of the device 600. As shown in FIG. 6, the device 600 may include a bus 610, a processor 620, a memory 630, an input component 640, an output component 650, and/or a communication component 660.

The bus 610 may include one or more components that enable wired and/or wireless communication among the components of the device 600. The bus 610 may couple together two or more components of FIG. 6, such as via operative coupling, communicative coupling, electronic coupling, and/or electric coupling. For example, the bus 610 may include an electrical connection (e.g., a wire, a trace, and/or a lead) and/or a wireless bus. The processor 620 may include a central processing unit, a graphics processing unit, a microprocessor, a controller, a microcontroller, a digital signal processor, a field-programmable gate array, an application-specific integrated circuit, and/or another type of processing component. The processor 620 may be implemented in hardware, firmware, or a combination of hardware and software. In some implementations, the processor 620 may include one or more processors capable of being programmed to perform one or more operations or processes described elsewhere herein.

The memory 630 may include volatile and/or nonvolatile memory. For example, the memory 630 may include random access memory (RAM), read only memory (ROM), a hard disk drive, and/or another type of memory (e.g., a flash memory, a magnetic memory, and/or an optical memory). The memory 630 may include internal memory (e.g., RAM, ROM, or a hard disk drive) and/or removable memory (e.g., removable via a universal serial bus connection). The memory 630 may be a non-transitory computer-readable medium. The memory 630 may store information, one or more instructions, and/or software (e.g., one or more software applications) related to the operation of the device 600. In some implementations, the memory 630 may include one or more memories that are coupled (e.g., communicatively coupled) to one or more processors (e.g., processor 620), such as via the bus 610. Communicative coupling between a processor 620 and a memory 630 may enable the processor 620 to read and/or process information stored in the memory 630 and/or to store information in the memory 630.

The input component 640 may enable the device 600 to receive input, such as user input and/or sensed input. For example, the input component 640 may include a touch screen, a keyboard, a keypad, a mouse, a button, a microphone, a switch, a sensor, a global positioning system sensor, a global navigation satellite system sensor, an accelerometer, a gyroscope, and/or an actuator. The output component 650 may enable the device 600 to provide output, such as via a display, a speaker, and/or a light-emitting diode. The communication component 660 may enable the device 600 to communicate with other devices via a wired connection and/or a wireless connection. For example, the communication component 660 may include a receiver, a transmitter, a transceiver, a modem, a network interface card, and/or an antenna.

The device 600 may perform one or more operations or processes described herein. For example, a non-transitory computer-readable medium (e.g., memory 630) may store a set of instructions (e.g., one or more instructions or code) for execution by the processor 620. The processor 620 may execute the set of instructions to perform one or more operations or processes described herein. In some implementations, execution of the set of instructions, by one or more processors 620, causes the one or more processors 620 and/or the device 600 to perform one or more operations or processes described herein. In some implementations, hardwired circuitry may be used instead of or in combination with the instructions to perform one or more operations or processes described herein. Additionally, or alternatively, the processor 620 may be configured to perform one or more operations or processes described herein. Thus, implementations described herein are not limited to any specific combination of hardware circuitry and software.

The number and arrangement of components shown in FIG. 6 are provided as an example. The device 600 may include additional components, fewer components, different components, or differently arranged components than those shown in FIG. 6. Additionally, or alternatively, a set of components (e.g., one or more components) of the device 600 may perform one or more functions described as being performed by another set of components of the device 600.

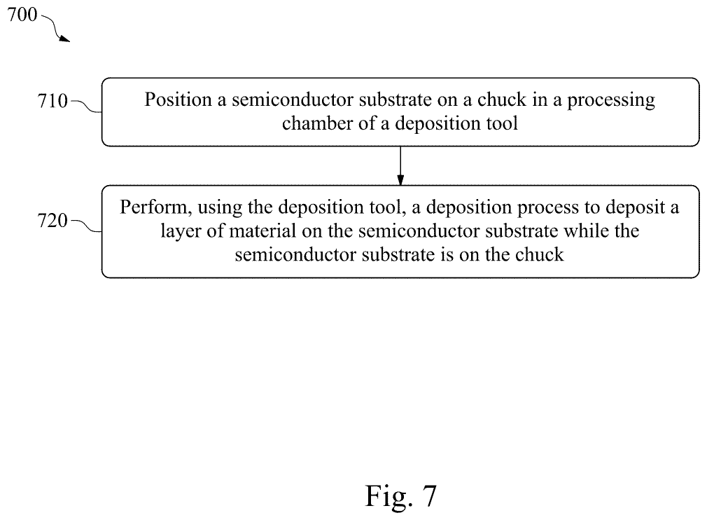

FIG. 7 is a flowchart of an example process 700 associated with performing a deposition operation using a deposition tool described herein. In some implementations, one or more process blocks of FIG. 7 are performed using a deposition tool (e.g., the deposition tool 200). In some implementations, one or more process blocks of FIG. 7 are performed by and/or using another device or a group of devices separate from or including the deposition tool 200, such as the RF bias source 220, the pulsed DC bias source 214, the mass flow controller(s) 222, the cryo pump 226a, the system pump 226b, the collimator bias source 230, the reflow DC source 242, the chuck actuator 244, and/or the controller 246. Additionally, or alternatively, one or more process blocks of FIG. 7 may be performed by one or more components of device 600, such as processor 620, memory 630, input component 640, output component 650, and/or communication component 660.

As shown in FIG. 7, process 700 may include positioning a semiconductor substrate on a chuck in a processing chamber of a deposition tool (block 710). For example, a semiconductor substrate 206 may be positioned on a rotatable chuck 208 in a processing chamber 202 of a deposition tool 200, as described herein.

As further shown in FIG. 7, process 700 may include performing, using the deposition tool, a deposition process to deposit a layer of material on the semiconductor substrate while the semiconductor substrate is on the chuck (block 720). For example, the deposition tool 200 may be used to perform a deposition process to deposit a layer of material (e.g., a layer of material 310) on the semiconductor substrate 206 while the semiconductor substrate 206 is on the rotatable chuck 208, as described herein. In some implementations, a pulsed DC bias source 214, that is used to apply a DC bias power to a material target 212 in the processing chamber 202, is pulsed based on a duty cycle 516 during the deposition process.

Process 700 may include additional implementations, such as any single implementation or any combination of implementations described below and/or in connection with one or more other processes described elsewhere herein.

In a first implementation, the DC bias power is pulsed for a plurality of on pulses 512 during the deposition process, and a temperature (Te) of electrons in a plasma 302 generated in the processing chamber 202 decreases between on pulses 512 of the plurality of on pulses 512.

In a second implementation, alone or in combination with the first implementation, an off time duration 514 between two on pulses 512 of the plurality of on pulses 512, corresponds to a relaxation time of the electrons in the plasma.

In a third implementation, alone or in combination with one or more of the first and second implementations, the temperature of the electrons in the plasma 302, at an end of an off time duration 514 between two on pulses 512 of the plurality of on pulses 512, is approximately 10% or less of the temperature of the electrons in the plasma 302 during the two on pulses 512.

In a fourth implementation, alone or in combination with one or more of the first through third implementations, performing the deposition process includes performing a first deposition operation to deposit material of the layer of material (e.g., the layer of material 310) onto the semiconductor substrate 206, where the pulsed DC bias source 214 is pulsed during the first deposition operation, and performing a second deposition operation to deposit additional material of the layer of material (e.g., the layer of material 310) onto the semiconductor substrate 206, where the pulsed DC bias source 214 is pulsed during the second deposition operation.

In a fifth implementation, alone or in combination with one or more of the first through fourth implementations, performing the deposition process includes performing a reflow operation to reflow the material of the layer of material (e.g., the layer of material 310) that was deposited onto the semiconductor substrate 206 in the first deposition operation.

In a sixth implementation, alone or in combination with one or more of the first through fifth implementations, the pulsed DC bias source 214 is pulsed during the deposition process at a pulse frequency that is included in a range of approximately 5 kilohertz to approximately 50 kilohertz.

In a seventh implementation, alone or in combination with one or more of the first through sixth implementations, process 700 includes adjusting the duty cycle 516 of the pulsed DC bias source 214 during the deposition process.

In an eighth implementation, alone or in combination with one or more of the first through seventh implementations, the duty cycle is included in a range of approximately 30% to approximately 70%.

Although FIG. 7 shows example blocks of process 700, in some implementations, process 700 includes additional blocks, fewer blocks, different blocks, or differently arranged blocks than those depicted in FIG. 7. Additionally, or alternatively, two or more of the blocks of process 700 may be performed in parallel.

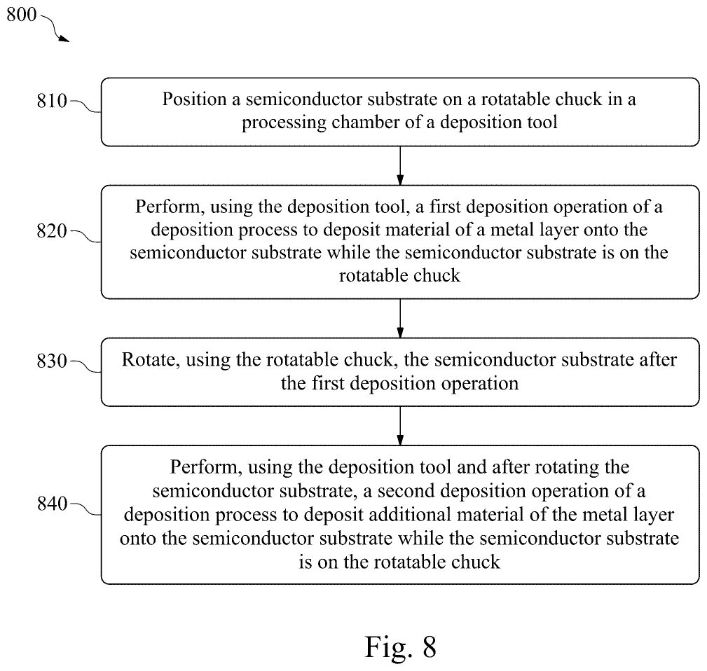

FIG. 8 is a flowchart of an example process 800 associated with performing a deposition operation using a deposition tool described herein. In some implementations, one or more process blocks of FIG. 8 are performed using a deposition tool (e.g., the deposition tool 200). In some implementations, one or more process blocks of FIG. 8 are performed by and/or using another device or a group of devices separate from or including the deposition tool 200, such as the RF bias source 220, the pulsed DC bias source 214, the mass flow controller(s) 222, the cryo pump 226a, the system pump 226b, the collimator bias source 230, the reflow DC source 242, the chuck actuator 244, and/or the controller 246, among other examples. Additionally, or alternatively, one or more process blocks of FIG. 8 may be performed by one or more components of device 600, such as processor 620, memory 630, input component 640, output component 650, and/or communication component 660.

As shown in FIG. 8, process 800 may include positioning a semiconductor substrate on a rotatable chuck in a processing chamber of a deposition tool (block 810). For example, a semiconductor substrate 206 may be positioned on a rotatable chuck 208 in a processing chamber 202 of the deposition tool 200, as described above.

As further shown in FIG. 8, process 800 may include performing, using the deposition tool, a first deposition operation of a deposition process to deposit material of a metal layer onto the semiconductor substrate while the semiconductor substrate is on the rotatable chuck (block 820). For example, the deposition tool 200 may be used to perform a first deposition operation of a deposition process to deposit material of a metal layer (e.g., a layer of material 310) onto the semiconductor substrate 206 while the semiconductor substrate 206 is on the rotatable chuck 208, as described above.

As further shown in FIG. 8, process 800 may include rotating, using the rotatable chuck, the semiconductor substrate after the first deposition operation (block 830). For example, the deposition tool 200 may be used to rotate, using the rotatable chuck 208, the semiconductor substrate 206 after the first deposition operation, as described above.

As further shown in FIG. 8, process 800 may include performing, using the deposition tool and after rotating the semiconductor substrate, a second deposition operation of a deposition process to deposit additional material of the metal layer onto the semiconductor substrate while the semiconductor substrate is on the rotatable chuck (block 840). For example, the deposition tool 200 may be used to perform, after rotating the semiconductor substrate 206, a second deposition operation of a deposition process to deposit additional material of the metal layer onto the semiconductor substrate 206 while the semiconductor substrate 206 is on the rotatable chuck 208, as described above.

Process 800 may include additional implementations, such as any single implementation or any combination of implementations described below and/or in connection with one or more other processes described elsewhere herein.

In a first implementation, rotating the semiconductor substrate 206 includes rotating the semiconductor substrate 206 greater than approximately 0 degrees and less than or equal to approximately 180 degrees.

In a second implementation, alone or in combination with the first implementation, process 800 includes performing a reflow operation on the semiconductor substrate 206 after the first deposition operation and prior to rotating the semiconductor substrate 206.

In a third implementation, alone or in combination with one or more of the first and second implementations, a pulsed DC bias source 214, that is used to apply a DC bias power to a material target 212 in the processing chamber 202, is pulsed based on a duty cycle 516 during the first deposition operation and during the second deposition operation.

In a fourth implementation, alone or in combination with one or more of the first through third implementations, the pulsed DC bias source 214 is pulsed during the first deposition operation to maintain an electron temperature (Te) in a plasma 302 in the processing chamber within a range of approximately 1 eV to approximately 10 eV.

In a fifth implementation, alone or in combination with one or more of the first through fourth implementations, the pulsed DC bias source 214, that is used to apply a DC bias power to the material target 212 in the processing chamber 202, is pulsed based on a first duty cycle 516 during the first deposition operation, and the pulsed DC bias source 214 is pulsed based on a second duty cycle 516 during the second deposition operation, where the first duty cycle 516 and the second duty cycle 516 are different duty cycles.

Although FIG. 8 shows example blocks of process 800, in some implementations, process 800 includes additional blocks, fewer blocks, different blocks, or differently arranged blocks than those depicted in FIG. 8. Additionally, or alternatively, two or more of the blocks of process 800 may be performed in parallel.

In this way, a deposition tool includes a rotatable chuck and/or a pulsed DC bias source. The rotatable chuck and/or the pulsed DC source enable the deposition tool to be used to deposit a layer onto a semiconductor substate with high horizontal thickness uniformity across the semiconductor substrate and/or with high vertical thickness symmetry. For example, the pulsed DC source may be used to pulse a DC power in the processing chamber to achieve a lower electron temperature in the processing chamber, which enables the material from a material target to be directed toward the semiconductor substrate in a highly directional manner. This enables a low angle of deposition to be achieved for depositing the material, which enables the material to be evenly and symmetrically deposited onto sidewalls of recesses in the semiconductor substrate. As another example, the rotatable chuck may be used to rotate the semiconductor substrate during deposition of the layer onto the semiconductor substrate to compensate for nonuniformities in the deposition rate of the layer across the semiconductor substrate. This enables a high horizontal thickness uniformity across the semiconductor substrate.

As described in greater detail above, some implementations described herein provide a method. The method includes positioning a semiconductor substrate on a chuck in a processing chamber of a deposition tool. The method includes performing, using the deposition tool, a deposition process to deposit a layer of material on the semiconductor substrate while the semiconductor substrate is on the chuck, where a DC bias source, that is used to apply a DC bias power to a material target in the processing chamber, is pulsed based on a duty cycle during the deposition process.

As described in greater detail above, some implementations described herein provide a method. The method includes positioning a semiconductor substrate on a rotatable chuck (208) in a processing chamber of a deposition tool. The method includes performing, using the deposition tool, a first deposition operation of a deposition process to deposit material of a metal layer onto the semiconductor substrate while the semiconductor substrate is on the rotatable chuck. The method includes rotating, using the rotatable chuck, the semiconductor substrate after the first deposition operation. The method includes performing, using the deposition tool and after rotating the semiconductor substrate, a second deposition operation of a deposition process to deposit additional material of the metal layer onto the semiconductor substrate while the semiconductor substrate is on the rotatable chuck.

As described in greater detail above, some implementations described herein provide a deposition tool. The deposition tool includes a processing chamber. The deposition tool includes a pedestal in the processing chamber. The deposition tool includes a chuck, on the pedestal in the processing chamber, configured to support a semiconductor substrate thereon. The deposition tool includes a chuck actuator configured to rotate the chuck.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

As used herein, the term “and/or,” when used in connection with a plurality of items, is intended to cover each of the plurality of items alone and any and all combinations of the plurality of items. For example, “A and/or B” covers “A and B,” “A and not B,” and “B and not A.”

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
positioning a semiconductor substrate on a chuck in a processing chamber of a deposition tool; and
performing, using the deposition tool, a deposition process to deposit a layer of material on the semiconductor substrate while the semiconductor substrate is on the chuck,
wherein a direct current (DC) bias source, that is used to apply a DC bias power to a material target in the processing chamber, is pulsed based on a duty cycle during the deposition process.

2. The method of claim 1, wherein the DC bias power is pulsed for a plurality of on pulses during the deposition process; and
wherein a temperature (Te) of electrons in a plasma generated in the processing chamber decreases between on pulses of the plurality of on pulses.

3. The method of claim 1, wherein the duty cycle is included in a range of approximately 30% to approximately 70%.

4. The method of claim 3, wherein the temperature of the electrons in the plasma, at an end of an off time duration between two on pulses of the plurality of on pulses, is approximately 10% or less of the temperature of the electrons in the plasma during the two on pulses.

5. The method of claim 1, wherein performing the deposition process comprises:
performing a first deposition operation to deposit material of the layer of material onto the semiconductor substrate,
wherein the DC bias source is pulsed during the first deposition operation; and
performing a second deposition operation to deposit additional material of the layer of material onto the semiconductor substrate,
wherein the DC bias source is pulsed during the second deposition operation.

6. The method of claim 5, wherein performing the deposition process comprises:
performing a reflow operation to reflow the material of the layer of material that was deposited onto the semiconductor substrate in the first deposition operation.

7. The method of claim 1, wherein the DC bias source is pulsed during the deposition process at a pulse frequency that is included in a range of approximately 5 kilohertz to approximately 50 kilohertz.

8. The method of claim 1, further comprising:
adjusting the duty cycle of the DC bias source during the deposition process.

9. A method, comprising:
positioning a semiconductor substrate on a rotatable chuck in a processing chamber of a deposition tool;
performing, using the deposition tool, a first deposition operation of a deposition process to deposit material of a metal layer onto the semiconductor substrate while the semiconductor substrate is on the rotatable chuck;
rotating, using the rotatable chuck, the semiconductor substrate after the first deposition operation; and
performing, using the deposition tool and after rotating the semiconductor substrate, a second deposition operation of a deposition process to deposit additional material of the metal layer onto the semiconductor substrate while the semiconductor substrate is on the rotatable chuck.

10. The method of claim 9, wherein rotating the semiconductor substrate comprises:
rotating the semiconductor substrate greater than approximately 0 degrees and less than or equal to approximately 180 degrees.

11. The method of claim 9, further comprising:
performing a reflow operation on the semiconductor substrate after the first deposition operation and prior to rotating the semiconductor substrate.

12. The method of claim 9, wherein a direct current (DC) bias source, that is used to apply a DC bias power to a material target in the processing chamber, is pulsed based on a duty cycle during the first deposition operation and during the second deposition operation.

13. The method of claim 12, wherein the DC bias source is pulsed during the first deposition operation to maintain an electron temperature (Te) in a plasma in the processing chamber within a range of approximately 1 electron volt (eV) to approximately 10 eV.

14. The method of claim 9, wherein a direct current (DC) bias source, that is used to apply a DC bias power to a material target in the processing chamber, is pulsed based on a first duty cycle during the first deposition operation;
wherein the DC bias source is pulsed based on a second duty cycle during the second deposition operation; and
wherein the first duty cycle and the second duty cycle are different duty cycles.

15. A deposition tool, comprising:
a processing chamber;
a pedestal in the processing chamber;
a chuck, on the pedestal in the processing chamber, configured to support a semiconductor substrate thereon; and
a chuck actuator configured to rotate the chuck.

16. The deposition tool of claim 15, further comprising:
a pulsed direct current (DC) source configured to apply a pulsed DC bias to a material target in the processing chamber.

17. The deposition tool of claim 16, further comprising:
a controller configured to:
provide one or more first signals to the pulsed DC source to cause the pulsed DC source to apply the pulsed DC bias to the material target during a deposition operation; and
provide one or more second signals to the chuck actuator to cause the chuck actuator to rotate the chuck after the deposition operation.

18. The deposition tool of claim 17, further comprising:
a plurality of reflow heater elements in the processing chamber; and
a reflow DC source coupled to the reflow heater elements.

19. The deposition tool of claim 18, wherein the controller is configured to:
provide one or more third signals to the reflow DC source to cause the reflow DC source to apply a reflow DC bias to the plurality of reflow heater elements after the deposition operation.

20. The deposition tool of claim 19, wherein the controller is configured to:
provide the one or more third signals to the reflow DC source to cause the reflow DC source to apply the reflow DC bias to the plurality of reflow heater elements prior to the chuck actuator rotating the chuck.
